(19) United States
(12) Patent Application Publication
(10) Pub. No.: US 2024/0237536 A1
(43) Pub. Date: Jul. 11, 2024

(54) ORGANIC THERMOELECTRIC ASSEMBLY WITH IMPROVED THERMOELECTRIC PERFORMANCE OF SATURATED MOLECULES USING NONCOVALENT ANCHOR-INDUCED ELECTRON DOPING OF SINGLE LAYER GRAPHENE ELECTRODE AND ORGANIC THERMOELECTRIC DEVICE INCLUDING SAME

(71) Applicant: KOREA UNIVERSITY RESEARCH AND BUSINESS FOUNDATION, Seoul (KR)

(72) Inventors: Hyo Jae YOON, Seoul (KR); Sohyun PARK, Seoul (KR)

(73) Assignee: KOREA UNIVERSITY RESEARCH AND BUSINESS FOUNDATION, Seoul (KR)

(21) Appl. No.: 18/572,460

(22) PCT Filed: Jun. 21, 2022
(86) PCT No.: PCT/KR2022/008807

§ 371 Date: Dec. 20, 2023

(30) Foreign Application Priority Data
Jun. 21, 2021 (KR) 10-2021-0080380

(51) Int. Cl. H10N 10/856; H10N 10/10; H10N 10/817

(52) U.S. Cl. CPC H10N 10/856; H10N 10/10; H10N 10/817

(57) ABSTRACT

The present invention relates to a nanoscale thermoelectric assembly assembled through non-covalent contact between graphene and molecules, and a thermoelectric device comprising same. The present invention ascertains an increase in the Seebeck value due to n-type doping induced by an electron interaction in non-covalent contact of molecules, and confirms the length dependence of the Seebeck value in a graphene-alkylamine SAM system, thereby enabling the development and industrial application of efficient organic thermoelectric devices at a molecular scale.

### TECHNICAL FIELD

The present invention relates to an organic thermoelectric junction in which an alkylamine (H₂NCₙ) is introduced onto single layer-graphene (SLG) to form a self-assembled monolayer (SAM) based on noncovalent contact and enhanced thermopower of the saturated molecules is achieved by doping of the graphene electrode, and a thermoelectric device including the thermoelectric junction.

### BACKGROUND ART

Thermoelectric materials are materials that convert thermal energy into electricity. This research area is very interesting both environmentally and scientifically in that thermal energy, the last form of energy, is recycled. Particularly, the thermal performance of microscale and nanoscale devices is becoming increasingly important but the relationship between structural features and thermal properties on an atomic scale remains incompletely understood. Attention in this research area is currently focusing on the development of thermoelectric materials with high efficiency and the identification of structural reasons for thermoelectric properties. Ultimately, more research at the molecular level needs to be done to achieve these goals.

The inventors of the present invention intend to propose the use of a graphene electrode as a strategy to enhance the thermopower of saturated molecules. Most previous studies on molecular thermoelectric devices have used π-electron-rich conjugated or aromatic molecules. Some of them have reported that an increase in conjugation length leads to enhanced thermopower. However, there have been no reports on methods for improving the thermopower of nonconjugated, nonaromatic molecules, that is, saturated hydrocarbons.

In this connection, a simple method for synthesizing single layer-graphene (SLG) has been developed. According to this conventional method, a high-quality stretchable graphene film is grown on and transferred to a nickel layer on a large scale by a chemical vapor deposition (CVD) technique (K. S. Kim, Y. Zhao, H. Jang, S. Y. Lee, J. M. Kim, K. S. Kim, J. H. Ahn, P. Kim, J. Y. Choi, B. H. Hong. Nature 2009, 457, 706).

The inventors of the present invention have also previously developed and reported a large-area system for thermoelectric measurements using an indium-gallium eutectic composition (S. Park, H. J. Yoon. Nano Lett. 2018, 18, 7715).

The present inventors have introduced, for the first time, a 2D material for thermoelectric measurements rather than a metal bottom electrode. Particularly, the present inventors have identified, for the first time, that the use of a graphene electrode can enhance the thermopower of alkylamine molecules as saturated molecules in contact with the graphene electrode, and finally arrived at the present invention.

### DETAILED DESCRIPTION OF THE INVENTION

### Problems to be Solved by the Invention

The inventors of the present invention intend to propose the use of a graphene electrode as an approach to enhancing the thermopower of a saturated hydrocarbon. The inventors of the present invention have found that a saturated hydrocarbon having a terminal amine group can form a monolayer on a graphene electrode, particularly the amine group can induce n-doping of the graphene electrode to form a new bandgap structure, which leads to enhanced thermopower.

### Means for Solving the Problems

Therefore, aspects of the present invention are intended to provide a thermoelectric junction in which an alkylamine (H₂NCₙ, where n is 4, 6, 8, . . . , 18) is introduced onto single layer-graphene (SLG) to form a self-assembled monolayer (SAM) based on noncovalent contact and a thermoelectric device including the thermoelectric junction. The present invention is also intended to determine higher thermopower of the thermoelectric junction than that of gold-alkanethiol junctions and identify its mechanism.

### Effects of the Invention

The thermoelectric junction of the present invention is constructed by introducing another type of 2D material such as graphene into a metal thermoelectric junction of metal-molecules (SAM). The thermopower (Seebeck coefficient) of the thermoelectric junction is significantly higher by a factor of about five than that of existing gold-alkanethiol junctions and is the highest among molecular junctions having an alkyl backbone reported to date.

In addition, the present invention identifies the mechanism for the concept of gap states caused by amine group-induced n-doping over the graphene electrode and proposes the possibility of achieving high thermopower by the use of the graphene electrode in the molecular-scale organic thermoelectric device. Therefore, the commercial marketability of the present invention in the field of molecular thermoelectrics will be enhanced and research on methods for further enhancing the thermopower of the junction at the molecular level will be continued.

### BRIEF DESCRIPTION OF THE DRAWINGS

FIG. 1 shows (a) schematic describing the structure of large-area thermoelectric junction according to the present invention, (b) molecules used in exemplary embodiments of the present invention, (c, d) correlation of energy barrier shape of molecular junction with Seebeck coefficient (the slope of transmission peak at E_{F}), (e, f) exemplary high resolution XPS spectra of C 1s and N 1s regions for H₂NC₄ and H₂NC₁₆ SAMs on SLG, (g) Raman spectra for SLG and H₂NCₙ SAMs on SLG, and (h) the G peak (cm⁻¹) shift in Raman spectra for H₂NCₙ SAMs on SLG.

FIG. 2 shows STM images of (a) bare SLG on SiO₂ and (b) H₂NCₙ SAM//SLG on SiO₂ acquired at height and current modes in −800 mV. The hexagonal pattern of SLG disappeared upon adsorption of H₂NCₙ.

FIG. 3 shows histograms of ΔV of alkylamine SAMs on formed graphene at different temperature differentials (ΔT=4, 8, 12 K).

FIG. 4 shows (a) comparison of length dependence of S values for Au/SCₙ and SLG//H₂NCₙ SAMs and (b) overall enhanced S values in the noncovalent interface as compared to the covalent one.

FIG. 5 shows ultraviolet photoelectron spectroscopy (UPS) spectra for Cu//SLG and Cu//SLG//HN₂Cₙ junctions to determine work function (WF).

FIG. 6 shows the structure of the field-effect transistor (FET) formed with SLG//HN₂Cₙ SAMs according to exemplary embodiments of the present invention.

FIG. 7 shows (a, b) IDs-Vas curves obtained by FET analysis for bare SLG (Si/SiO₂//SLG) and SLG with H₂NC₈ SAM (Si/SiO₂//SLG//H₂NC₈), respectively, and (c) plots of V_{CNP} and degree of E_{F} shift as a function of alkyl chain length.

FIG. 8 shows I_{DS}−V_{GS} plots obtained by FET analysis with H₂NCₙ SAMs.

FIG. 9 shows (a) band structures with E_{F} shift and change of DOS for SLG//H₂NCₙ SAMs, (b) plot of simulated Seebeck coefficient, and (c) comparison in length dependence between experimental and theoretical S values as a function of the molecular length.

FIG. 10 shows (a) the structures of H₂NCₙ SAM (n=16) on SLG with (2×2) and (3×3) unit cells, (b) the DOS spectrum of H₂NC₁₆//SLG ((2×2) and (3×3) unit cells), and (c) the plot of change of DOS between H₂NC₁₆//SLG and bare SLG near 0 eV. The new in-gap states near −0.1 eV upon the physisorption.

FIG. 11 shows the adsorption (binding) energy (E_{b}) with variations of (a) the chain length with packing density, (b) tilt angle, and (c) N—C of graphene distance.

### BEST MODE FOR CARRYING OUT THE INVENTION

The present invention will now be described in more detail.

The present invention provides an organic thermoelectric junction including single layer-graphene (SLG) and a self-assembled monolayer (SAM) formed by self-assembly of n-alkylamine (H₂NCₙ, where n is an integer from 4 to 30) molecules on the single layer-graphene.

According to one embodiment of the present invention, the single layer-graphene may be in noncovalent contact with the self-assembled monolayer formed by self-assembly of n-alkylamine molecules.

According to one embodiment of the present invention, n-type doping may be induced by electronic interaction at the noncovalent contact between the amine group of the n-alkylamine and the graphene.

According to one embodiment of the present invention, the thermoelectric properties of the organic thermoelectric junction may increase with increasing n.

The present invention also provides an organic thermoelectric device including a first electrode, a second electrode, and the organic thermoelectric junction.

According to one embodiment of the present invention, the single layer-graphene may function as the first electrode and n-type doping may be induced by electronic interaction at the noncovalent contact between the amine group of the n-alkylamine of the SAM and the graphene.

### MODE FOR CARRYING OUT THE INVENTION

The present invention will be more specifically explained with reference to the following examples. However, these examples are provided for illustrative purposes and do not serve to limit the scope of the invention. It will be obvious to those skilled in the art that various modifications and changes are possible without departing from the scope and spirit of the invention.

### 1. Preparation of Single-Layer Graphene (SLG) and SAMs

The inventors of the present invention prepared SLG on copper foil following the previously reported procedure based on CVD (Nature 2009, 457, 706) and confirmed the quality and single layer structure with Raman spectroscopy and scanning tunneling microscopy (STM). Noncovalent interaction of amine anchor with SLG allows reversible adsorption and desorption, leading to well packed monolayers without alteration of the chemical structure of SLG.

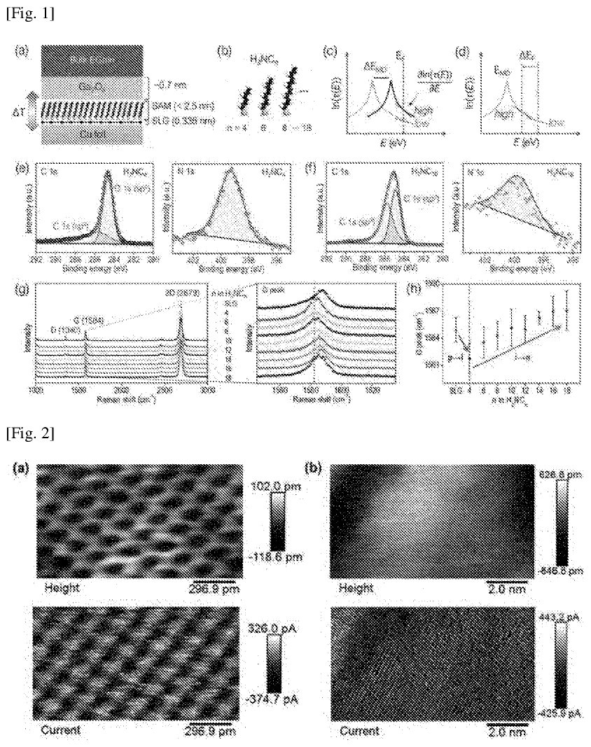

As shown in (a) of FIG. 1, to form SAMs, SLG on copper foil (Cu//SLG) was incubated in an 18 mM solution of H₂NCₙ with a mixture of methanol (HPLC grade) and tetrahydrofuran (THF, HPLC grade) with a volume ratio of 1:9.

### 2. Confirmation of Formation of SAMs

The formation of SAMs was confirmed by scanning tunneling microscopy (STM) and X-ray photoelectron spectroscopy (XPS).

In STM analysis, the hexagonal pattern of SLG disappeared upon adsorption of H₂NCₙ (FIG. 2). In high resolution XPS spectra, the C1s signal was presented by a combination of two peaks at 284.7 and 285.8 eV, corresponding to sp² and sp³ carbons, respectively. The peak integration ratio of sp³ to sp² increased with increasing the alkane chain length ((e, f) of FIG. 1). The binding energies of N1s were observed at 400 eV ((e, f) of FIG. 1). The integration ratio of N1s to sp³ C1s peaks decreased as the alkane chain length increased. These observations confirmed the formation of desired SAMs on SLG.

The formation of SAM on SLG was further confirmed by Raman spectroscopy. The Raman spectra exhibited G and 2D bands at around 1580 cm⁻¹ and 2680 cm⁻¹, respectively ((g) of FIG. 1). The G band is the main spectral feature of carbon-based materials including graphene, and 2D band means the perfect symmetry of graphene hexagonal lattice. These bands represent the phonon interactions at the I′ and K points in the Brillouin zone, respectively. D band was also observed at 1340 cm⁻¹. The D band signifies disorder band due to lattice motion away from the middle of the Brillouin zone. The intensity of the D band of SLG remained unchanged upon SAM formation regardless of the alkyl chain length, which confirms the non-covalent contact between SLG and H₂NCₙ. The quality of SLG can be determined by the 2D/G signal ratio: the 2D/G signal ratio of SLG was above 2, indicating its good quality.

For ease of Raman spectroscopic analysis, SLG was transferred from Cu foil onto SiO₂/Si substrate. The transfer was especially intended to eliminate the dominant Raman signal of Cu. Upon SAM formation on SLG, the G band position was blue-shifted with respect to the position of intact SLG ((g, h) of FIG. 1). This was attributed to n-type doping of SLG by the amine anchor. As the alkyl chain length increased, the degree of blue shift of G band gradually increased, which confirmed the formation of desired SAMs. The n-type doping of SLG upon SAM formation was further confirmed by the field effect transistor (FET) analysis.

### 3. Thermovoltage Measurements

EGaIn conical tips were formed, junctions were constructed, and thermovoltage (ΔV, μV) was measured following the methods reported in the literature. (Nano Lett. 2018, 18, 7715)

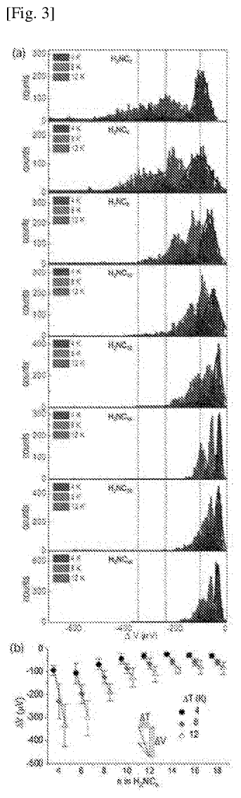

(a) of FIG. 3 shows histograms of ΔV of alkylamine SAMs formed on graphene at different temperature differentials (ΔT=4, 8, 12 K). The yield of working thermoelectric junctions ranged from 64-93%. Through fitting of the histograms with single Gaussian curves, mean values of ΔV (ΔVₘₑₐₙ) and standard deviation (σ_{ΔV}) were derived. These values are shown in Table 1.

TABLE 1

| n in | T | Samples | Tips | Junctions | | | | Yield |
|---|---|---|---|---|---|---|---|---|
| (H₂Nₙ) | (K) | (#) | (#) | (#) | Counts | ΔVₘₑₐₙ ± σ_{ΔV} | S_{SAM} (μV/K) | (%) |
| 4 | 4 | 3 | 13 | 39 | 2964 | −95 ± 22 | 30.6 ± 3.4 | 84 |
| | 8 | 3 | 13 | 39 | 2964 | −229 ± 76 | | 71 |
| | 12 | 3 | 14 | 39 | 2964 | −334 ± 91 | | 64 |
| 6 | 4 | 3 | 14 | 40 | 3040 | −107 ± 44 | 24.9 ± 1.2 | 88 |
| | 8 | 3 | 14 | 40 | 3040 | −197 ± 42 | | 82 |
| | 12 | 3 | 14 | 40 | 3040 | −302 ± 76 | | 81 |
| 8 | 4 | 3 | 14 | 40 | 3040 | −68 ± 23 | 16.0 ± 0.7 | 90 |
| | 8 | 3 | 14 | 40 | 3040 | −124 ± 26 | | 81 |
| | 12 | 3 | 14 | 40 | 3040 | −190 ± 37 | | 82 |
| 10 | 4 | 3 | 14 | 40 | 3040 | −44 ± 22 | 11.2 ± 0.3 | 92 |
| | 8 | 3 | 14 | 40 | 3040 | −87 ± 21 | | 88 |
| | 12 | 3 | 14 | 40 | 3040 | −126 ± 41 | | 86 |
| 12 | 4 | 3 | 14 | 40 | 3040 | −31 ± 13 | 10.6 ± 0.7 | 93 |
| | 8 | 3 | 14 | 40 | 3040 | −66 ± 24 | | 88 |
| | 12 | 3 | 14 | 40 | 3040 | −111 ± 33 | | 85 |
| 14 | 4 | 3 | 14 | 40 | 3040 | −25 ± 9 | 9.8 ± 0.5 | 90 |
| | 8 | 3 | 14 | 40 | 3040 | −57 ± 12 | | 90 |
| | 12 | 3 | 14 | 40 | 3040 | −96 ± 14 | | 88 |
| 16 | 4 | 3 | 14 | 40 | 3040 | −29 ± 10 | 8.0 ± 0.7 | 92 |
| | 8 | 3 | 14 | 40 | 3040 | −59 ± 15 | | 80 |
| | 12 | 3 | 14 | 40 | 3040 | −81 ± 30 | | 86 |
| 18 | 4 | 3 | 14 | 40 | 3040 | −32 ± 8 | 7.8 ± 0.2 | 90 |
| | 8 | 3 | 14 | 40 | 3040 | −59 ± 10 | | 88 |
| | 12 | 3 | 14 | 40 | 3040 | −85 ± 27 | | 88 |

(b) of FIG. 3 shows the ΔV trends as a function of ΔT for the inventive junctions. All the measured ΔV values were negative. All the SAMs exhibited increased ΔV as ΔT increased, which yielded positive Seebeck coefficient (S=−ΔV/ΔT) values. The value of σ_{ΔV} increased with increasing ΔT and with shortening the alkane chain length. The dependence of σ_{ΔV} on ΔT and the length could be explained by the difference in packing structure of monolayers. Strong lateral interaction between alkane backbone in long alkyl amines would yield solid-like monolayers whereas short alkyl amines generate relatively disordered monolayers, which is reminiscent of alkanethiolate SAMs.

### 4. Confirmation of Enhanced Seebeck Coefficient (S) by the Noncovalent Contact

To examine the effect of noncovalent contact on the thermopower of the inventive thermoelectric junctions, S values for SLG//H₂NCₙ//Ga₂O₃/EGaIn and Au/SCₙ//Ga₂O₃/EGaIn junctions were compared (Note that these two junctions have identical EGaIn top-electrode and alkane backbone, which made it possible to single out reliably the effect of different contact nature).

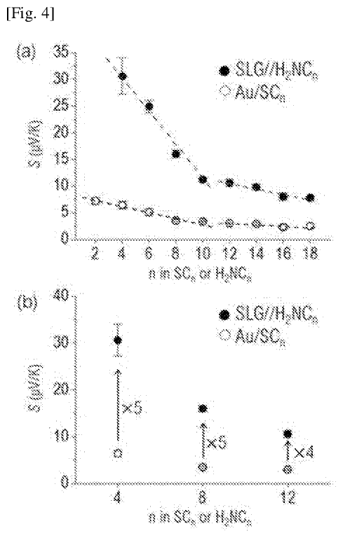

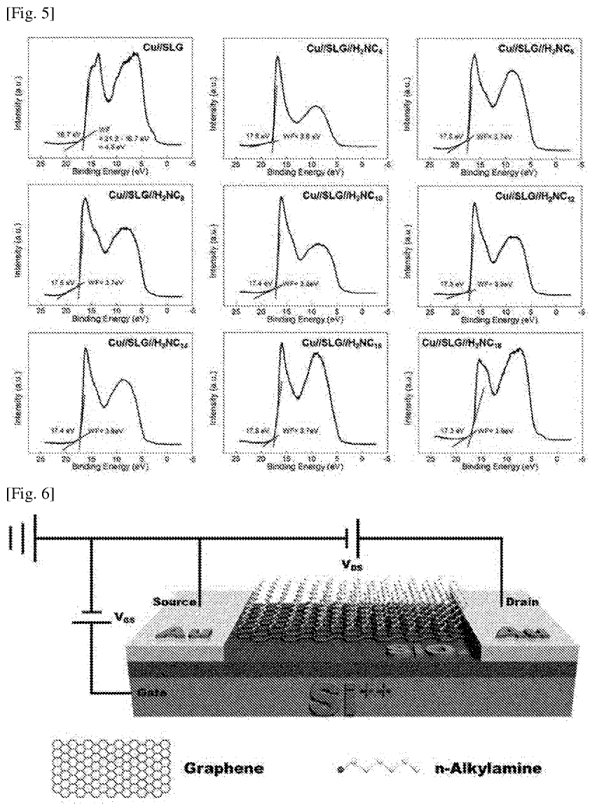

(a) of FIG. 4 compares the length dependence of S values for Au/SCₙ and SLG//H₂NCₙ SAMs. Both systems exhibited the same crossover point, n=10. Notably, there were overall enhancements of S values in the noncovalent junction as compared to the analogous covalent junction ((b) of FIG. 4).

The value of S in SLG//H₂NC₄ (30.6 μV/K) was higher by a factor of five than that in Au/SC₄ (6.4 μV/K); there was a three-fold difference in the value of S between SLG//H₂NC₁₈ (7.8 μV/K) and Au/SC₁₈ (2.5 V/K). The enhanced thermopower indicates that the electronic structural effect contributes significantly to the observed difference in S values between SLG//H₂NCₙ and Au/SCₙ SAMs.

### 5. Length Dependence of Seebeck Coefficient (S)

Length dependence of S can be explained by the following semiempirical parametric equation: (ACS Nano 2011, 5, 551)

$$S = Sc + {β}^{S} \times d$$

where S_{C} is the Seebeck coefficient at the hypothetical non-shorting junction that does not possess an insulating organic component; β^{S} is the rate of S change as a function of molecular length (d in Å or the number of repeating units such as the number of carbon atoms).

A linear regression of S value against molecular length for the short molecules from C₄NH₂ to C₁₀NH₂ was observed ((a) of FIG. 4). The values of β^{S} and S_{C} for the regression were −3.1±0.4 μV·(K·n_{C})⁻¹ and 41.7±3.5 V/K, respectively. There was a transition in β^{S} from −3.1±0.4 to −0.47±0.07 μV·(K·n_{C})⁻¹ at C₁₀NH₂.

### 6. Electronic Structure-Thermopower Relationship

Ultraviolet photoelectron spectroscopy (UPS) measurements were conducted for HN₂Cₙ junctions to determine work function (WF) (FIG. 5). SLG on Cu foil exhibited WF of 4.5 eV, and, upon SAM formation, it decreased to 3.8 eV. The reduction of WF in combination with the Raman spectroscopic analysis clearly indicates the n-type doping by the amine anchor.

The electronic structure of SLG//H₂NCₙ SAMs was further characterized with the field-effect transistor (FET) method. The source and drain electrodes of field effect transistor (FET) devices were fabricated by thermal deposition in order of chrome (3 nm) and gold (60 nm) metal layers on the Si/SiO₂ wafer with the patterned stencil masks. The graphene film on PMMA substrate was transferred onto the gold-patterned Si/SiO₂ wafer. Then, the substrate was dipped into acetone to remove PMMA for 1 hour. Each graphene device was isolated by electron beam lithography, with gate width and length of 100 and 40 μm, respectively. Finally, in order to remove impurities, charge puddles, and mechanical wrinkles, graphene device was thermally annealed at 200° C. for 5 hours under the atmosphere of argon as a carrier gas (100 sccm) in low vacuum condition. The structure of the FET formed with SLG//H₂NCₙ SAMs is shown in FIG. 6.

The FET method allows to determine charge neutrality point, V_{CNP} (Dirac point), which is intimately related to doping level, n (also called charge carrier concentration) and Fermi level, E_{F}, according to the following equation: (Nano Lett. 2010, 10, 490; Nanotechnology 2015, 26, 475202.)

$$n = \frac{{C}_{ox}}{e} Δ {V}_{CNP} = \frac{{ϵ}_{0} {κ}_{ox}}{{ed}_{ox}} Δ {V}_{CNP} \\ {E}_{F} = ℏ {v}_{F} \sqrt{π n} = ℏ {v}_{F} \sqrt{\frac{{πϵ}_{0} {κ}_{ox} Δ {V}_{CNP}}{{ed}_{ox}}}$$

Here, ϵ₀ is the free space permittivity (e²GeV⁻¹fm⁻¹); κₒₓ is the relative permittivity of gate material, 300 nm SiO₂ (κₒₓ=3.9); ΔV_{CNP} is the change of the applied gate voltage across a dielectric with thickness dₒₓ (=300 nm); e is the elementary charge (C); h is the reduced Planck constant (eVs); and v_{F} is the Fermi velocity with speed of light (m/s).

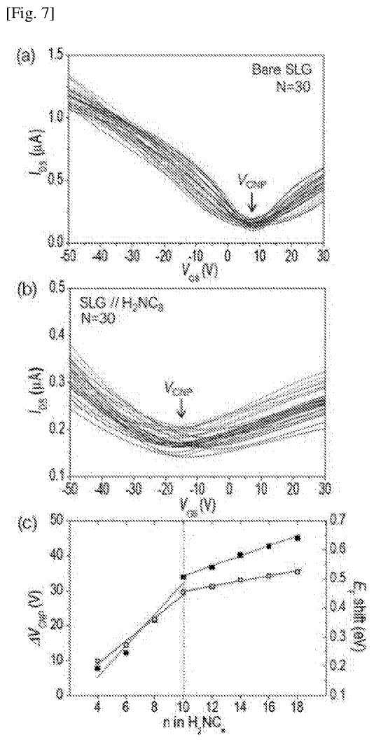

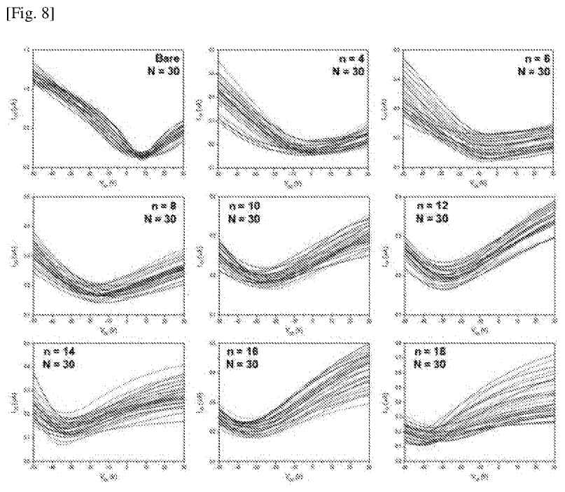

FET devices with the SAMs were fabricated and V_{CNP} and derived E_{F} were measured. The graphene (SLG) exhibited V_{CNP}>0, which was indicative of p-type doping ((a) of FIG. 7). This is due to the long exposure time in the air, doping by water molecules during copper etch and wet transfer processes, and back-gate in FET measurements, considering that pristine graphene theoretically exhibits V_{CNP}=0. The p-doping was consistent with the result of Raman spectroscopic analysis. The current-voltage curve (I_{DS}−V_{GS}) was measured on 30 different junctions in each SAM; I_{DS} and V_{GS} correspond to current measured between drain and source and voltage applied across gate and source, respectively. As shown in (b) of FIG. 7, upon the formation of SAM, V_{CNP} decreased relative to that of bare SLG, and particularly, the values of V_{CNP} gradually decreased as the alkyl chain length increased, indicating n-type doping ((c) of FIG. 7), consistent with the result of Raman spectroscopic analysis ((g) of FIG. 1). As the length of alkyl chain increased, the packing becomes denser, leading to more nitrogen atoms per unit area, better n-doping, and more shift of E_{F}. Indeed, the literature indicates that the surface coverage on graphene and the packing stabilization energy in H₂NCₙ SAMs show considerable transitions at n=10, which is consistent with the above result and proves the inventors' reasoning ((c) of FIG. 7). The results of FET measurements for the SAMs with other lengths are shown in FIG. 8.

### 7. Doping-Induced Gap States

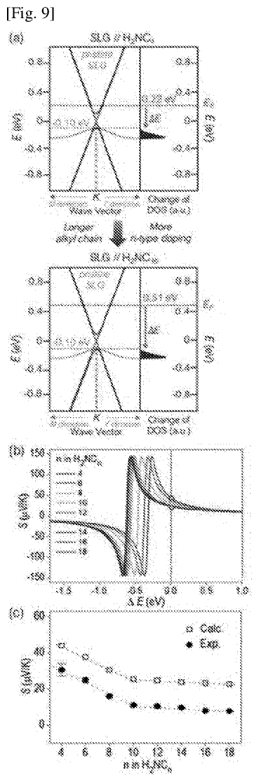

According to a tight binding model, a perfect-crystalline and undoped SLG shows a band structure with zero gap, a.k.a. Dirac cone (blue line in (a) of FIG. 9). Hexagonal lattice system of graphene causes a small gap. Examples of such cases include formation of crystal defects, increase in strain, doping induced by chemi-/physisorption. Molecular adsorption on the graphene surface forms new highest occupied molecular orbital (HOMO) and lowest unoccupied molecular orbital (LUMO). This affects the band structure of graphene, and consequently the molecules act as dopants.

In the physisorption, the nitrogen atom of the amine group (—NH₂) in H₂NCₙ interacts with the carbon atoms that forms the SLG to generate new in-gap states. Ab initio calculations were conducted to examine the creation of such energy states upon physisorption of the amine molecules on SLG, and what factors do and do not influence the states.

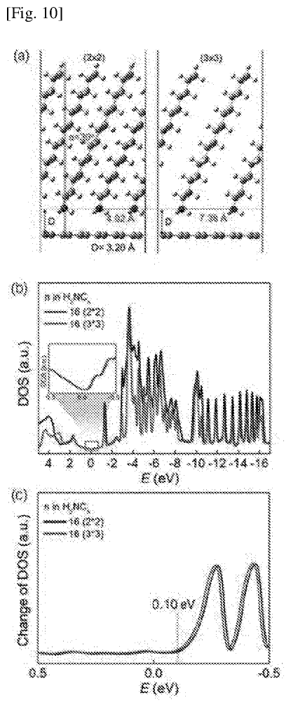

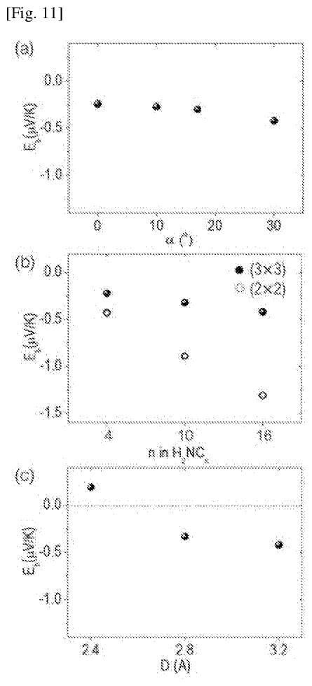

Upon the physisorption, new in-gap states near −0.1 eV appeared (FIG. 10). The newly generated in-gap states did not vary according to the length of alkyl chain, tilt angle of molecules with respect to the surface normal, and distance between SLG surface and nitrogen atom. A noticeable feature in these calculations was that, as the length of alkyl chain increased, the SAM was more densely packed with higher adsorption energy (FIG. 11). The calculation results explicitly indicate that the shift of E_{F} (by up to 0.52 e V relative to the pristine SLG) determined by the FET experiments was not due to any difference in supramolecular packing structure according to different molecular length. Rather, it was attributed to the more nitrogen atoms per unit area for longer H₂NCₙ molecules, which in turn leads to more n-type doping over the SLG.

(a) of FIG. 9 shows the band structures schematically drawn based on the calculations and FET analysis and summarizes the change of electronic structure before and after physisorption of the amine molecules.

Physisorption of H₂NCₙ SAM on SLG surface leads to creation of doping-induced gap states (DIGS), and the increase of density of state (DOS) near the gap (black-filled peaks in (a) of FIG. 9). As the alkyl chain increases, E_{F} is shifted to a more positive value, while the gap state is fixed at −0.1 eV ((a) of FIG. 9). As a result, the energy offset for the DIGS increases. This is consistent with the FET analysis (shown in (c) of FIG. 7). The dependence of doping degree on the alkyl chain length could be attributed to the enhanced stability of physisorption and electron density arising from better packed SAMs in longer molecules. These experiments indicate that the new DIGS govern the thermopower of the inventive junction.

### 8. Simulation of S

The S value of the electrode-SAMs-electrode junction was simulated by the following equations (Phys. Rev. B 2003, 67, 241403):

$$τ ( E ) = \frac{{Γ}_{L} \cdot {Γ}_{R}}{{( \frac{{Γ}_{L} + {Γ}_{R}}{2} )}^{2} + {( E - {E}_{MO} )}^{2}} \\ S = - \frac{{π}^{2} {k}_{B}^{2} T}{3 e} \frac{\partial ln ( τ ( E ) )}{\partial E} {\vert}_{E = {E}_{F}}$$

Here, τ(E) is the transmission coefficient; E_{MO} is the energy level of accessible molecular orbital; and Γ_{L} and Γ_{R} are the coupling constants due to left (bottom) and right (top) contacts, respectively; e is the charge of an electron; k_{B} is the Boltzmann constant; E_{F} is the Fermi level of electrode; and T is the average absolute temperature of the junction. According to the model, the slope of Lorentzian-shaped transmission coefficient at E_{F} corresponds to S. As the slope is steeper, the value of S becomes larger. In this simulation, it was assumed that both bottom and top electrodes are identical and the coupling constants (Γ) with the SAMs are both 0.050 eV, which has been used for van der Waals contacts in EGaIn junctions, are used. (Chem. Commun. 2019, 55, 8780)

(b) of FIG. 9 shows the plot of τ(E) simulated with ΔE values obtained from FET measurements. As shown in (b) of FIG. 9, the calculated S values well concurred with the experimental ones. The values obtained through the simulation of S are summarized in Table 2.

TABLE 2

| n (H₂NCₙ) | Calc. S | Exp. S |
|---|---|---|
| 4 | 62.4 | 30.6 |
| 6 | 50.7 | 24.9 |
| 8 | 38.8 | 16.0 |
| 10 | 31.1 | 11.2 |
| 12 | 29.9 | 10.6 |
| 14 | 28.6 | 9.8 |
| 16 | 27.8 | 8.0 |
| 18 | 27.1 | 7.8 |

The value of β^{S} varied from −3.1±0.1 to −0.35±0.03 μV/(KnC)⁻¹ at n=10, which accounted for the experimentally observed transition of slope (−3.1±0.4 to −0.43±0.03 μV/(KnC)⁻¹ at n=10) ((c) of FIG. 9).

The change in β^{S} at H₂NC₁₀ would be due to the different packing structure for long and short alkyl SAMs. It has been established that liquid-like SAMs transition into solid-like SAMs at SC₁₀. Similarly, in SLG//H₂NCₙ SAMs, it was given that packing and surface coverage change gradually after H₂NC₁₀. The change in BS may be due to the transition in transport mechanism from direct tunneling to hopping.

This data supports the dominant effect of n-doping induced new bandgap structure on thermopower of junctions. While the overall trends of length dependence of simulated S values were consistent with those of experimentally determined ones, there were marginal deviations in absolute values of S between them. This could be explained by the following reasons.

First, the deviations could be attributed to the complexity arising from the supramolecular packing structure in monolayers. In the model of the equation discussed earlier, S is determined based on an ideal Lorentzian-shaped transmission peak, which can fit single-molecule systems well. In a real junction, molecules within monolayers are disordered to some extent, and the defects can cause a change in the shape of transmission function from Lorentzian to Gaussian. This may reduce the slope at E_{F} and be responsible for the decreased S values in experiments.

Second, the effect of Γ on S would be not negligible. When Γ=0.050 eV, values of S for n=4, 6, 8 in H₂NCₙ SAMs were 43.7, 30.3 and 20.3 μV/K, respectively. When Γ was increased by a factor of four (to 0.20 eV), the values of S were decreased to 38.8, 26.0, and 19.8 μV/K, respectively. In contrast, for the long molecular length regime (n>10), the S value did not significantly depend on the variation of. This result indicates that the S value become more sensitive to the change of Γ as ΔE is smaller and the alkane chain length of HN₂Cₙ is shorter. Therefore, the deviations between experimental and theoretical S values in the short molecules may reflect the uncertainty of Γ.

Third, there may be a noticeable difference in ΔE between the SAMs with and without the EGaIn top-contact. (Nano Lett. 2019, 19, 545) The top electrode-induced renormalization may be nontrivial in the junctions and responsible for the observed deviations. (Phys. Rev. Lett. 2006, 97, 216405; Nat. Nanotechnol. 2013, 8, 282)

9. Comparison with Au/S Covalent Contact

Thermopower of both noncovalent (SLG//H₂NCₙ) and covalent (Au/SCₙ) junction relies on the orbital mixing between anchor and electrode at the contact, yet it was found for the first time in the present invention that the underlying mechanism differs in detail.

S of Au/SCₙ system is governed by the chemisorption induced gap states (CIGS), which stems from orbital mixing of S—Au moiety with a small amount of adjacent hydrocarbons of alkane chain. In short alkyl chains (n≤10), the CIGS depends on the length of alkyl chain and dominates transmission coefficient, whereas it becomes insignificant in the regime of long alkanes (n≥10). In contrast, the thermopower of SLG//H₂NCₙ system is dominated by creation of the new gap states caused by the amine anchor-induced doping.

According to the present invention, it was demonstrated that thermopower in saturated molecules can be enhanced by single-layer graphene electrode. The experiments on the thermoelectric junction of the present invention show S values in the noncovalent junction are larger (by up to five-fold) than those of the covalent junction.

The underlying mechanism for the enhancement of S is revealed to be the n-type doping induced by electronic interaction at the noncovalent contact between amine anchor and graphene. The physisorption-induced doping yields new doping-induced gap states near Fermi level of single-layer graphene. The alkyl chain length of amine molecules significantly affects the position of Fermi level of single-layer graphene and not the in-gap states. These account for thermopower of the molecular junctions and its length dependence. As can be seen from the Examples section, the simulation of S with the Mott formula proves the proposed mechanism.

The present invention proposes for the first time that control over molecule-electrode contact in molecular-scale thermoelectric devices can improve Seebeck coefficient of saturated molecules and may augur well for developing efficient organic thermoelectric devices.

### INDUSTRIAL APPLICABILITY

According to the present invention, the alkylamine can be functionalized with a photo-, redox- or magneto-reactive a group by interaction with the 2D material, which paves the way for the development of a new type of thermoelectric molecular junction that is expected to be highly applicable to various electronics industries in the future. Therefore, the thermoelectric junction is considered an eco-friendly approach that efficiently recycles thermal energy, which is the last form of energy, ultimately contributing to solving energy problems.

1. An organic thermoelectric junction comprising single layer-graphene (SLG) and a self-assembled monolayer (SAM) formed by self-assembly of n-alkylamine (H₂NCₙ, where n is an integer from 4 to 30) molecules on the single layer-graphene.

2. The organic thermoelectric junction according to claim 1, wherein the single layer-graphene is in noncovalent contact with the self-assembled monolayer formed by self-assembly of n-alkylamine molecules.

3. The organic thermoelectric junction according to claim 1, wherein n-type doping is induced by electronic interaction at the noncovalent contact between the amine group of the n-alkylamine and the graphene.

4. The organic thermoelectric junction according to claim 1, wherein the thermoelectric properties of the organic thermoelectric junction increase with increasing n.

5. An organic thermoelectric device comprising a first electrode, a second electrode, and an organic thermoelectric junction wherein the organic thermoelectric junction comprises single layer-graphene (SLG) and a self-assembled monolayer (SAM) formed by self-assembly of n-alkylamine (H₂NCₙ, where n is an integer from 4 to 30) molecules on the single layer-graphene.

6. The organic thermoelectric device according to claim 5, wherein the single layer-graphene functions as the first electrode.

7. The organic thermoelectric device according to claim 5, wherein n-type doping is induced by electronic interaction at the noncovalent contact between the amine group of the n-alkylamine of the SAM and the graphene.

8. The organic thermoelectric device according to claim 5, wherein the thermoelectric properties of the organic thermoelectric junction increase with increasing n.
